(19) United States
(12) Patent Application Publication
(10) Pub. No.: US 2009/0165842 A1
(43) Pub. Date: Jul. 2, 2009

(54) SOLID CONCENTRATOR WITH TOTAL INTERNAL SECONDARY REFLECTION

(76) Inventors: Mark McDonald, Milpitas, CA (US); Peter Young, San Francisco, CA (US); Stephen J. Horne, El Granada, CA (US)

Correspondence Address: BUCKLEY, MASCHOFF & TALWALKAR LLC, 50 LOCUST AVENUE, NEW CANAAN, CT, 06840, US

(21) Appl. No.: 12/046,903

(22) Filed: Mar. 12, 2008

Related U.S. Application Data
(60) Provisional application No. 61/017,432, filed on Dec. 28, 2007.

(51) Int. Cl. H01L 31/052; H01L 31/0232

(52) U.S. Cl. 136/246; 136/259

(57) ABSTRACT

A system includes a solid light-transmissive element comprising a first surface and a second surface, first reflective material disposed on the second surface of the light-transmissive element, and a solar cell to convert light received at the first surface to electrical current. The light received at the first surface may pass through the light-transmissive element, reflect off the first reflective material and intercept an area of an interface between the first surface and an adjacent environment at an angle of incidence greater than arc sin(nₓ/n_{y}), where nₓ=an index of refraction of the adjacent environment and n_{y}=an index of refraction of the light-transmissive element at the first surface.

### CROSS-REFERENCE TO RELATED APPLICATION

The present application claims priority to U.S. Provisional Patent Application Ser. No. 61/017,432, filed on Dec. 28, 2007 and entitled “Solid Concentrator With Total Internal Secondary Reflection”, the contents of which are incorporated herein by reference for all purposes.

### BACKGROUND

A solar radiation concentrator may convert received solar radiation (i.e., sunlight) into a concentrated beam and direct the concentrated beam onto a photovoltaic (or, solar) cell. The cell, in turn, may generate electrical current based on photons of the concentrated beam. A concentrator thereby enables a small solar cell to generate electrical current based on photons received over a larger area.

U.S. Patent Application Publication No. 2006/0231133 describes several types of concentrating solar collectors. As generally described therein, solar radiation enters a solid transparent element and strikes reflective material disposed on a convex surface (i.e., a primary mirror) of the element. The radiation is reflected toward reflective material disposed on a smaller and opposite concave surface (i.e., a secondary mirror), and is reflected thereby toward an even smaller area from which a solar cell may receive the radiation. Such operation may allow the concentrator to convert the received solar radiation to electricity using smaller solar cells than would otherwise be required.

The reflective material disposed on the secondary mirror prevents some solar radiation from reaching the primary mirror. The secondary mirror is located near the focus of the primary mirror in order to minimize this shading. However, this location requires the secondary mirror to exhibit a steeply curved aspheric surface and to satisfy precise geometric tolerances with respect to the primary mirror. Formation of such a primary mirror and a secondary mirror on opposite sides of an optically-transparent element (e.g., glass) is difficult and expensive.

Improved solar concentrator designs are desired. Such designs may provide increased power generation per unit area, improved manufacturability, decreased cost, and/or other benefits.

### BRIEF DESCRIPTION OF THE DRAWINGS

FIG. 1 is a cutaway side view of a solid concentrator according to some embodiments.

FIG. 2 is a perspective top view of the FIG. 1 solid concentrator according to some embodiments.

FIG. 3 a perspective exploded view of a solid concentrator according to some embodiments.

FIG. 4 is a perspective view of an array of solid concentrators according to some embodiments.

FIG. 5 is a cutaway side view of a solid concentrator and lens according to some embodiments.

FIG. 6 is a perspective top view of the FIG. 5 solid concentrator and lens according to some embodiments.

FIG. 7 is a perspective view of a solid concentrator and lens according to some embodiments.

FIG. 8 is a perspective view of an array of solid concentrators and lenses according to some embodiments.

### DESCRIPTION

The following description is provided to enable any person in the art to make and use the described embodiments and sets forth the best mode contemplated for carrying out some embodiments. Various modifications, however, will remain readily apparent to those in the art.

FIG. 1 is a cutaway side view of apparatus 100 according to some embodiments. Apparatus 100 includes substantially light-transparent core 105 and solar cell 110. Core 105 may be composed of any suitable material or combination of materials. According to some embodiments, core 105 is configured to manipulate and/or pass desired wavelengths of light. Core 105 may be molded from low-iron glass, formed from a single piece of clear plastic, or formed from separate pieces which are glued or otherwise coupled together to form core 105.

Solar cell 110 may comprise a III-V solar cell, a II-VI solar cell, a silicon solar cell, or any other type of solar cell that is or becomes known. Solar cell 110 may comprise any number of active, dielectric and metallization layers, and may be fabricated using any suitable methods that are or become known. Solar cell 110 is capable of generating charge carriers (i.e., holes and electrons) in response to received photons. Although solar cell 110 is shown recessed into core 105, solar cell 110 may be disposed at any suitable position with respect to core 105.

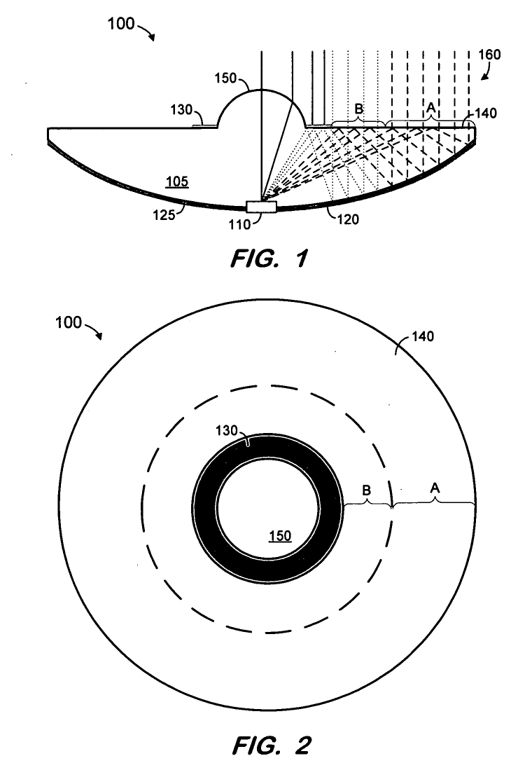

Primary mirror 120 is disposed on convex surface 125 of core 105 and reflective material 130 is disposed on flat surface 140 of core 105 as shown. FIG. 2, which is a top view of the FIG. 1 apparatus, shows reflective material 130 disposed in a ring-like shape. Primary mirror 120 and reflective material 130 may comprise any suitable reflective material, including but not limited to silver or aluminum. Primary mirror 120 and reflective material 130 may be fabricated by sputtering or otherwise depositing a reflective material directly onto the larger convex surface of core 105 and the illustrated ring-shaped area of surface 140. A reflective side of the deposited material faces the surface on which the material is deposited.

Refractive lens 150 is disposed opposite from primary mirror 120. Core 105 and lens 150 may comprise a single molded piece, or lens 150 may be fabricated separately and attached to core 105. Accordingly, lens 150 may comprise a material different from core 105 in some embodiments.

In operation, incoming on-axis (e.g., normal to surface 140) light 160 passes through ambient air and is received at surface 140 and lens 150 of apparatus 100. For clarity, FIG. 1 shows only incoming light 160 received on one half of apparatus 100. Some of incoming light 160 is received at area A of surface 140 and is represented by dashed lines in FIG. 1. This light 160 received at area A passes through core 105 and reflects off of primary mirror 120. The reflected light returns to an area at the interface of surface 140 and ambient air, where the reflected light experiences total internal reflection.

More specifically, and with respect to the FIG. 1 embodiment, the angle at which the reflected light 160 meets the area at the interface is greater than arc sin (nₐᵢᵣ/n_{core}), where nₓ represents a refractive index of medium x. The reflective properties (efficiency, chromatic aberration, etc.) of a total internal reflection are superior to that of a reflective material coating. The reflected light proceeds from the interface toward an active area of solar cell 110 as shown.

Dotted lines represent the incoming light 160 received at area B of surface 140. This light 160 passes through core 105 and reflects off of primary mirror 120 as described above. This reflected light also returns to an area at the interface of surface 140 and ambient air, however, the angle at which the light meets the area is less than or equal to arc sin(nₐᵢᵣ/n_{core}). Since this light would not experience total internal reflection, reflective material 130 serves to reflect the light toward the active area of solar cell 110.

The reflectivity of a non-total internal reflection (angle of incidence≦arc sin (nₐᵢᵣ/n_{core}) may in some instances be greater than that provided by a reflective coating such as material 130. Therefore, the exterior diameter of material 130 may be reduced so that the light received at some small annular zone immediately interior to area A reflects off of the air/surface 140 interface via a non-total internal reflection.

As also shown in FIG. 1, incoming light 160 may reach reflective coating 130. This light 160 is stopped at 130 and is not directed into core 105 and toward solar cell 110. Incoming light 160 is also received by lens 150. Lens 150 is shaped to refract the received light and to direct the light to the active area of solar cell 110. Lens 150 may comprise a Fresnel lens, a continuous lens, a gradient index lens or some combination thereof. Refracted light may introduce chromatic dispersion, therefore some embodiments are designed to reduce a size and refractive angle of lens 150. In some embodiments, the shape of lens 150 is less difficult to manufacture than the secondary mirror surfaces of prior designs.

The dimensions of area A, area B, reflective material 130, and lens 150 are subject to the geometry of primary mirror 120 and the refractive index of core 105. In some embodiments, primary mirror 120 is paraboloidial-shaped and the refractive index of core 105 is ˜1.5. Any suitable mirror geometry and core material having any suitable refractive index may be used in some embodiments.

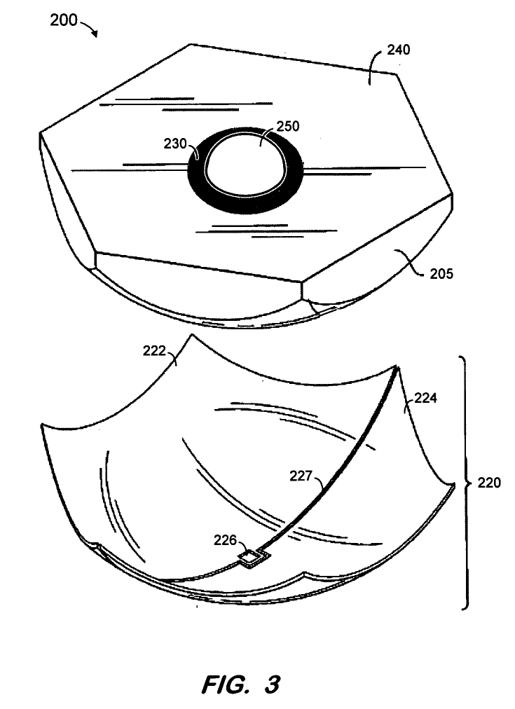

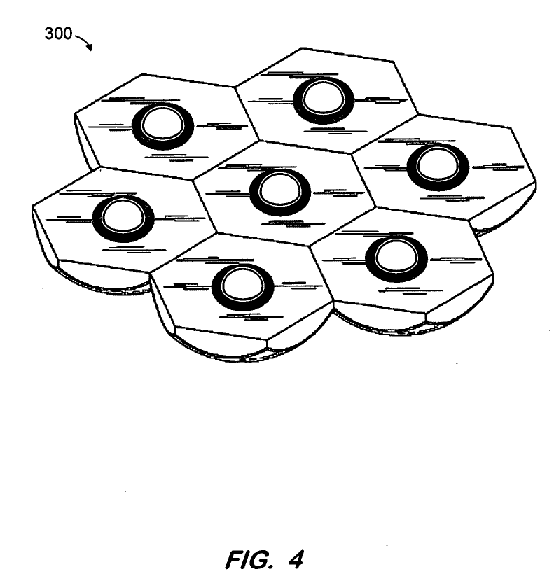

FIG. 3 is an exploded view of apparatus 200 according to some embodiments. Apparatus 200 includes core 205, primary mirror 220, reflective material 230, surface 240, and lens 250. Apparatus 200 may operate similarly to apparatus 100 described above.

An upper periphery of core 205 of FIG. 3 includes six contiguous facets. This six-sided arrangement may facilitate the formation of large arrays of apparatus 200 in a space-efficient manner. FIG. 4 provides a perspective view of array 300 of apparatuses 200 according to some embodiments. Embodiments are not limited to the illustrated arrangement. For example, some embodiments may include four contiguous facets or no facets (e.g., apparatus 100). Irregular or semi-regular tessellations (e.g., a combination of octagons and squares) may also be employed.

Primary mirror 220 includes conductive portion 222 and conductive portion 224. Conductive portion 222 defines opening 226 through which concentrated light may exit apparatus 200 and be received by a solar cell. Primary mirror 120 of apparatus 100 may be substituted with primary mirror 220 and/or any other primary mirror illustrated and/or described herein. Alternatively, primary mirror 220 of apparatus 200 may be substituted with primary mirror 120 and/or any other primary mirror illustrated and/or described herein.

Gap 227 is defined between conductive portions 222 and 224 to facilitate electrical isolation thereof. Accordingly, conductive portions 222 and 224 of primary mirror 220 may create a conductive path for electrical current generated by the solar cell. Conductive portions 222 and 224 may also, as described in above-mentioned Application Publication No. 2006/0231133, electrically link photovoltaic cells of adjacent collectors in a concentrating solar collector array.

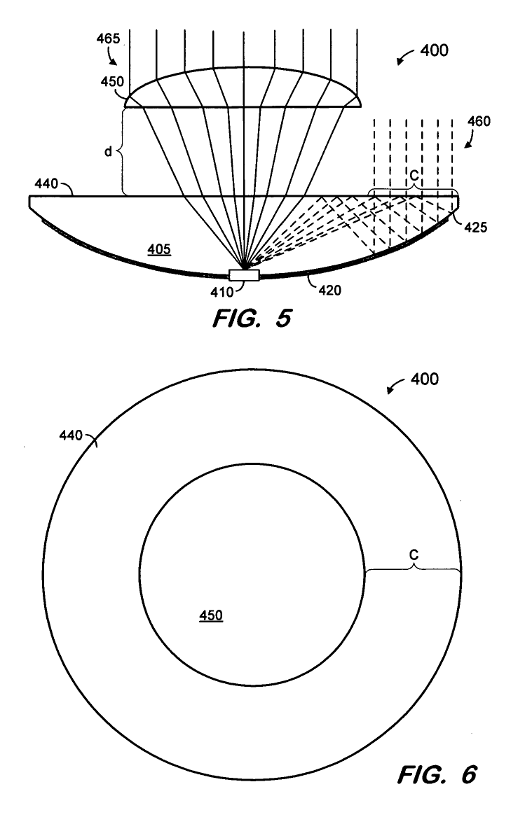

FIG. 5 is a cutaway side view and FIG. 6 is a perspective top view of apparatus 400 according to some embodiments. Apparatus 400 includes substantially light-transparent core 405, solar cell 410, and primary mirror 420, which may be implemented as described with respect to core 105, cell 110 and mirror 120 of apparatus 100.

Apparatus 400 also includes lens 450 disposed at a distance d from surface 440 of core 405. Lens 450 may comprise a material different from core 450 according to some embodiments. Lens 450 may reduce a need for reflective material disposed on surface 440. As will be described below, some embodiments of apparatus 400 include reflective material on surface 440.

According to some embodiments, molding tolerances associated with lens 450 and core 405 provide improved manufacturability and decreased cost.

In operation, incoming light 460 passes through ambient air and is received at surface 440 of apparatus 400. FIG. 5 shows only incoming light 460 received on one half of surface 440 for clarity. Light 460 received at area C passes through core 405 and reflects off of primary mirror 420. The reflected light returns to the interface of surface 440 and ambient air where it experiences total internal reflection as described above. The reflected light proceeds from the interface toward an active area of solar cell 410 as shown.

For some combinations of primary mirror geometries and core indices of refraction, some or all of the incoming on-axis light may be reflected using total internal reflection. For example, primary mirror 420 is not present along a periphery of surface 425 of core 405. Light passing through core 405 and received at this periphery may intercept surface 425 at an angle sufficient to cause total internal reflection of the light toward surface 440. Even if primary mirror 420 was present along the periphery of surface 425, the light incident thereto (if received at a sufficient angle) may be reflected via total internal reflection rather than by primary mirror 420. As total internal reflection exhibits substantially higher reflectivity than alternate reflective materials, the foregoing feature may improve system efficiency.

Lens 450 receives incoming light 465. Lens 450 is shaped to refract light 465 and to direct the light toward surface 440. As shown in FIG. 5, light 465 is refracted three times prior to reaching solar cell 410. Distance d, a shape of lens 450, and a refractive index of lens 450 are therefore selected such that these refractions result in the delivery of light 465 to solar cell 410. In addition, any suitable geometry of mirror 420 and refractive index of core 405 may be used in some embodiments.

In some embodiments, some incoming normal light may miss lens 465 and intercept surface 440 at an area other than area C. Reflective material may be deposited on appropriate locations of surface 440 to reflect this light toward solar cell 410. This reflective material may be disposed between lens 450 and surface 440 in some embodiments.

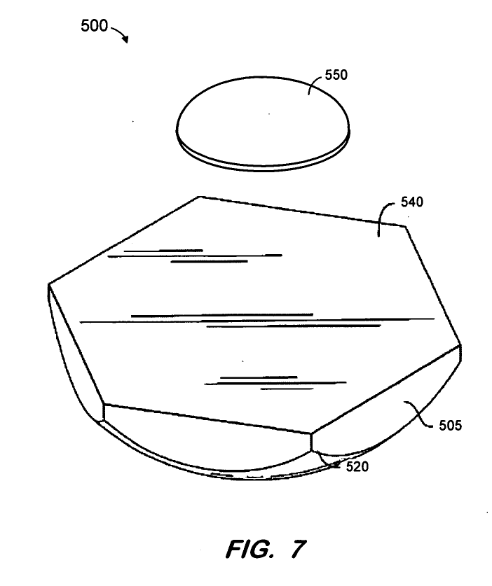

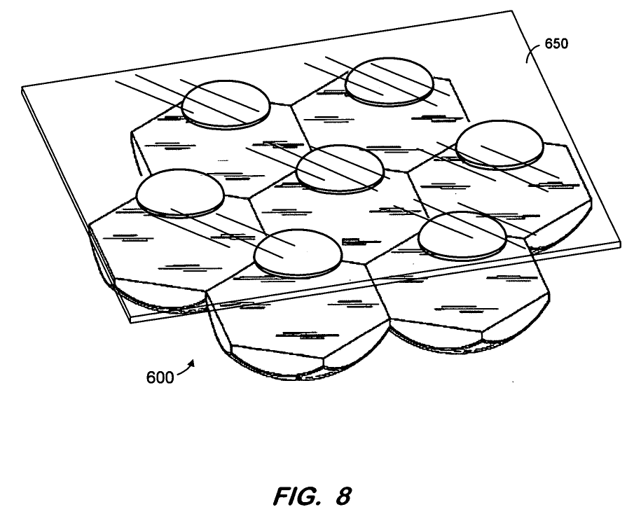

FIG. 7 is a perspective view of apparatus 500 according to some embodiments. Apparatus 500 includes core 505, primary mirror 520, surface 540, and lens 550. Apparatus 500 may operate similarly to apparatus 400 described above.

An upper periphery of core 505 includes six contiguous facets, but embodiments are not limited thereto. Primary mirror 520 may comprise a contiguous material, may be separated as described with respect to mirror 220, and/or may comprise any suitable configuration.

FIG. 4 provides a perspective view of array 600 of apparatuses 500 according to some embodiments. Each lens 550 is coupled to cover glass 650, which provides environmental protection as well as a mounting surface for lenses 550. Each lens may be coupled to glass 650 using an epoxy or other optically-transparent material. Selection of such a material may take into account a refractive index of glass 650, a refractive index of lenses 550, and/or thermal expansion properties to glass 650 and lenses 550.

A position of cover glass 650 may determine a distance d between lenses 550 and cores 505 of array 600. In some embodiments, lenses 550 are mounted such that glass 650 is located between lenses 550 and cores 505.

What is claimed is:

1. An apparatus comprising:
a solid light-transmissive element comprising a first surface and a second surface;
first reflective material disposed on the second surface of the light-transmissive element; and
a solar cell to convert light received at the first surface to electrical current,
wherein the light received at the first surface is to pass through the light-transmissive element, reflect off the first reflective material and intercept an area of an interface between the first surface and an adjacent environment at an angle of incidence greater than arc sin(nₓ/n_{y}), wherein nₓ=an index of refraction of the adjacent environment and n_{y}=an index of refraction of the light-transmissive element at the first surface.

2. An apparatus according to claim 1, wherein no reflective material is disposed on the first surface at the area of the interface.

3. An apparatus according to claim 1, further comprising:
a lens coaxial with the element, the lens to receive second light and to refract the second light for conversion by the solar cell.

4. An apparatus according to claim 3, wherein the lens is separate from the first surface of the light-transmissive element.

5. An apparatus according to claim 3, further comprising:
second reflective material disposed on the first surface at a second area of the interface,
wherein third light received at the first surface is to pass through the light-transmissive element, reflect off the first reflective material, intercept the second area of the interface at an angle of incidence less than or equal to arc sin(nₓ/n_{y}), and reflect off of the second reflective material for conversion by the solar cell.

6. An apparatus according to claim 3,
wherein third light received at the first surface is to:
pass through the light-transmissive element;
intercept an area of a second interface between the second surface and an environment adjacent to the second surface at an angle of incidence greater than arc sin(nₐ/n_{b}), wherein nₐ=an index of refraction of the environment adjacent to the second surface and n_{b}=an index of refraction of the light-transmissive element at the second surface; and
reflect off the area of the second interface toward the first surface.

7. An apparatus according to claim 1, further comprising:
second reflective material disposed on the first surface at a second area of the interface,
wherein second light received at the first surface is to pass through the light-transmissive element, reflect off the first reflective material, intercept the second area of the interface at an angle of incidence less than or equal to arc sin(nₓ/n_{y}), and reflect off of the second reflective material for conversion by the solar cell.

8. An apparatus according to claim 7,
wherein third light received at the first surface is to pass through the light-transmissive element, reflect off the first reflective material, intercept a third area of the interface at an angle of incidence less than or equal to arc sin(nₓ/n_{y}), and partially reflect off the third area of the interface for conversion by the solar cell.

9. An apparatus according to claim 7,
wherein third light received at the first surface is to:
pass through the light-transmissive element;
intercept an area of a second interface between the second surface and an environment adjacent to the second surface at an angle of incidence greater than arc sin(nₐ/n_{b}), wherein nₐ=an index of refraction of the environment adjacent to the second surface and n_{b}=an index of refraction of the light-transmissive element at the second surface; and
reflect off the area of the second interface toward the first surface.

10. An apparatus according to claim 1, wherein the first light and the second light are substantially parallel to an axis of the light-transmissive element.

11. A method comprising:
receiving first light at a first surface of a solid light-transmissive element;
passing the first light through the first surface and through the light-transmissive element;
reflecting the passed first light toward the first surface;
receiving the reflected first light at an area of an interface between the first surface and an adjacent environment, and at an angle of incidence greater than arc sin(nₓ/n_{y}), wherein nₓ=an index of refraction of the adjacent environment and n_{y}=an index of refraction of the light-transmissive element at the first surface;
reflecting the first light off the area of the interface; and
converting the first light to electrical current with a solar cell.

12. A method according to claim 11, wherein no reflective material is disposed on the first surface at the area of the interface.

13. A method according to claim 1, further comprising:
receiving second light at a lens coaxial with the element;
refracting the second light with the lens; and
converting the second light to electrical current with the solar cell.

14. A method according to claim 13, further comprising:
passing the refracted second light through air prior to converting the second light.

15. A method according to claim 13, further comprising:
receiving third light at the first surface;
passing the third light through the light-transmissive element;
reflecting the passed third light toward the first surface;
receiving the reflected third light at a second area of the interface, and at an angle of incidence less than or equal to arc sin(nₓ/n_{y});
reflecting the reflected third light off of second reflective material disposed on the first surface at the second area of the interface; and
converting the third light to electrical current with the solar cell.

16. A method according to claim 13, further comprising:
receiving third light at the first surface;
passing the third light through the light-transmissive element;
receiving the passed third light at an area of a second interface between a second surface of the element and an environment adjacent to the second surface, and at an angle of incidence greater than arc sin(nₐ/n_{b}), wherein nₐ=an index of refraction of the environment adjacent to the second surface and n_{b}=an index of refraction of the light-transmissive element at the second surface; and
reflecting the passed third light off the area of the second interface and toward the first surface.

17. A method according to claim 11, further comprising:
receiving second light at the first surface;
passing the second light through the light-transmissive element;
reflecting the passed second light toward the first surface;
receiving the reflected second light at a second area of the interface, and at an angle of incidence less than or equal to arc sin(nₓ/n_{y});
reflecting the reflected second light off of second reflective material disposed on the first surface at the second area of the interface; and
converting the second light to electrical current with the solar cell.

18. A method according to claim 17, further comprising:
receiving third light at the first surface;
passing the third light through the light-transmissive element;
reflecting the passed third light toward the first surface;
receiving the reflected third light at a second area of the interface, and at an angle of incidence less than or equal to arc sin(nₓ/n_{y});
partially reflecting the reflected third light off of the second area of the interface; and
converting the partially reflected third light to electrical current with the solar cell,
wherein no reflective material is disposed on the first surface at the second area of the interface.

19. A method according to claim 17, further comprising:
receiving third light at the first surface;
passing the third light through the light-transmissive element;
receiving the passed third light at an area of a second interface between a second surface of the element and an environment adjacent to the second surface, and at an angle of incidence greater than arc sin(nₐ/n_{b}), wherein nₐ=an index of refraction of the environment adjacent to the second surface and n_{b}=an index of refraction of the light-transmissive element at the second surface; and
reflecting the passed third light off the area of the second interface and toward the first surface.

20. A method according to claim 11, wherein the first light is received substantially parallel to an axis of the light-transmissive element.
